(19) United States
(12) Patent Application Publication
(10) Pub. No.: US 2012/0073960 A1
(43) Pub. Date: Mar. 29, 2012

(54) MAGNETRON SPUTTERING APPARATUS AND ELECTRONIC COMPONENT MANUFACTURING METHOD

(75) Inventors: Yohsuke SHIBUYA, Machida-shi (JP); Masayoshi Ikeda, Hachioji-shi (JP); Yasumi Sago, Tachikawa-shi (JP)

(73) Assignee: CANON ANELVA CORPORATION, Kawasaki-shi (JP)

(21) Appl. No.: 13/223,830

(22) Filed: Sep. 1, 2011

Related U.S. Application Data
(63) Continuation of application No. PCT/JP2010/007599, filed on Dec. 28, 2010.

(30) Foreign Application Priority Data
Dec. 28, 2009 (JP) 2009-298237

(51) Int. Cl. C23C 14/35

(52) U.S. Cl. 204/192.22; 204/298.16; 204/192.12

(57) ABSTRACT

A magnetron sputtering apparatus includes a cathode electrode having a first surface and a second surface opposite to the first surface, a target attachable to the first surface of the cathode electrode, and a magnet unit which is adjacent to the second surface of the cathode electrode and forms a magnetic field on the target surface. The magnet unit includes a plurality of magnet pieces each having a first magnet member which is magnetized in a direction perpendicular to the target and is arranged with a magnetic pole end face oriented toward the target, and a second magnet member which is magnetized opposite to the first magnet member in the direction perpendicular to the target and is arranged in contact with the first magnet member with a magnetic pole end face being oriented toward the target.

### RELATED APPLICATIONS

This application claims priority as a continuation application under 35 U.S.C. §120 to PCT/JP2010/007599, which was filed as an International Application on Dec. 28, 2010 designating the U.S., and which claims priority to Japanese Application No. 2009-298238, filed on Dec. 29, 2009. The entire contents of these applications are hereby incorporated by reference in their entireties.

### TECHNICAL FIELD

The present invention relates to a magnetron sputtering apparatus used in a semiconductor manufacturing process and the like, and an electronic component manufacturing method using it.

### BACKGROUND ART

A known example of a sputtering method is a magnetron sputtering method as described in PTL1. In this magnetron sputtering method, a magnet is arranged on the rear surface of a target electrode. A magnetic field is formed on the target surface to confine electrons near the target. Ionization can be efficiently performed even at low pressures, generating a high-density plasma. The magnetron sputtering method has been put into practical use in various fields because it can form a high-quality film at high deposition rate. The magnetron sputtering method has been applied even to the manufacture of semiconductor devices and electronic components, and is regarded as an important technique which determines the characteristics of these devices and the like.

### CITATION LIST

### Patent Literature

PTL1: Japanese Patent Publication No. 6-92632

### SUMMARY OF INVENTION

### Technical Problem

Recently, magnet units capable of forming a stronger magnetic field near the target have been developed to increase the plasma density near the target.

However, a magnetic field formed by the magnet unit needs to be small near the substrate to prevent problems such as charge-up damage. Since the plasma density depends on the density of a magnetic flux in the atmosphere, the magnetic flux density near the substrate becomes nonuniform depending on the magnet arrangement, resulting in nonuniform plasma density. For example, in the manufacture of a field effect transistor, a gate insulating film is exposed to the plasma when forming a gate electrode on the gate insulating film. Nonuniformly stored charges apply an electrical stress (flow of a tunnel current by a high electric field) to the gate insulating film, damaging and degrading it. The degree of nonuniformity of the plasma and the charge-up damage occurrence ratio rise as the magnetic flux density on the substrate side increases.

The present invention has been made to solve the above problems, and has as its objective to provide a magnetron sputtering apparatus having a magnet unit capable of increasing the plasma density near the target and decreasing the magnetic field strength on the substrate side.

### Solution to Problem

A magnetron sputtering apparatus according to an aspect of the present invention comprises a cathode electrode having a first surface capable of attaching a target and a second surface opposite to the first surface; and a magnet unit which is adjacent to the second surface of the cathode electrode and forms a magnetic field on a surface of the target, the magnet unit including a plurality of magnet pieces each having a first magnet member which is magnetized in a direction perpendicular to the surface of the target and is arranged with a magnetic pole end face oriented toward the target, and a second magnet member which is magnetized opposite to the first magnet member in the direction perpendicular to the target and is arranged in contact with the first magnet member with a magnetic pole end face being oriented toward the target, wherein the plurality of magnet pieces are arranged like a ring spaced each other in a circumferential direction to form a ring-like magnetic field for magnetron sputtering on the surface of the target, wherein the magnet unit is adapted to be rotatable around an rotating shaft perpendicular to the surface of the target and to form a magnetic field in a direction rotating along the surface of the target, and wherein the plurality of magnet pieces are arranged so that the center of the ring-like magnetic field is decentered from the rotating shaft.

Heteropolar magnet members are paired and arranged in contact with each other while their magnetic pole end faces having the strongest magnetic force are oriented toward the target. This arrangement can form a magnetic field which is strong near the target and is suppressed on the substrate side. Forming a ring-like magnetic field by the magnet pieces can suppress an imbalance in magnetic force between the inside and the outside. A magnetic field which suppresses divergence of magnetic lines of force and is suppressed on the substrate side can therefore be formed.

### Advantageous Effects of Invention

The present invention increases the magnetic flux density near the target and decreases it near the substrate.

Other features and advantages of the present invention will be apparent from the following description taken in conjunction with the accompanying drawings, in which like reference characters designate the same or similar parts throughout the figures thereof.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1 is a schematic view exemplifying a sputtering apparatus according to the present invention;

FIG. 2A is a schematic plan view showing a magnet unit according to an embodiment;

FIG. 2B is a schematic view showing a magnet piece according to the embodiment;

FIG. 3 is a sectional view exemplifying the manufacture of an electronic component to which the present invention is applicable;

FIG. 4 is a graph showing the horizontal magnetic flux density dependence of the film resistivity;

FIG. 5 is a graph showing attenuation of the horizontal magnetic flux density along the Z-axis in a cathode magnet according to the present invention; and

FIG. 6 is a view showing a magnet in Comparative Example.

### DESCRIPTION OF EMBODIMENTS

A preferred embodiment of the present invention will be described below.

[Apparatus Arrangement]

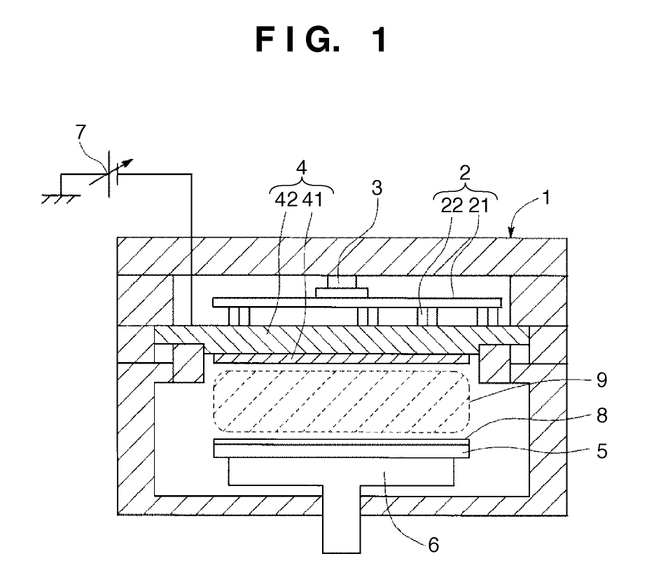

FIG. 1 is a schematic sectional view showing the arrangement of a magnetron sputtering apparatus according to the embodiment.

In the magnetron sputtering apparatus in FIG. 1, a deposition chamber 1 incorporates a wafer holder 5 capable of holding a substrate 8, and a cathode unit 4 formed from a target 41 arranged to face the substrate 8 and a target electrode (cathode electrode) 42 capable of applying a voltage to the target 41. The target 41 is attached to the first surface of the target electrode 42 that faces the wafer holder 5. A magnet unit 2 is attached to the second surface opposite to the first surface to form a magnetic field on the surface of the target 41. The magnet unit 2 includes a plate 21 made of a material such as a metal, and a plurality of magnet pieces 22 attached to the plate 21. The magnet unit 2 can rotate about the center of a rotating shaft 3 perpendicular to the surface of the target 41. By forming a magnetic field rotating along the surface of the target 41, erosion uniformly occurs on the entire surface of the target 41. Reference numeral 6 denotes an elevating mechanism for vertically driving the wafer holder 5.

Although not shown, the deposition chamber 1 is connected to a vacuum pump and a gas introduction system capable of introducing sputtering gas, so as to be able to evacuate the interior of the deposition chamber 1 and introduce sputtering gas. After introducing sputtering gas, a glow discharge high-voltage power supply 7 supplies power to the target 41, generating a high-density sputtering plasma 9 confined in a magnetic circuit formed by the magnet unit 2. At this time, electrons in the plasma are trapped near the surface of the target 41 by a drift motion in the magnetic circuit formed by the magnet unit 2, promoting ionization of gas molecules. A high-density plasma is formed at a point on the surface of the target 41 where the magnetic flux density in the horizontal direction (horizontal magnetic flux density) is high. Ions in the plasma 9 are accelerated by the cathode sheath and collide with the target 41. The constituent atoms of the target 41 are sputtered and deposited on the surface of the substrate 8, forming a thin film.

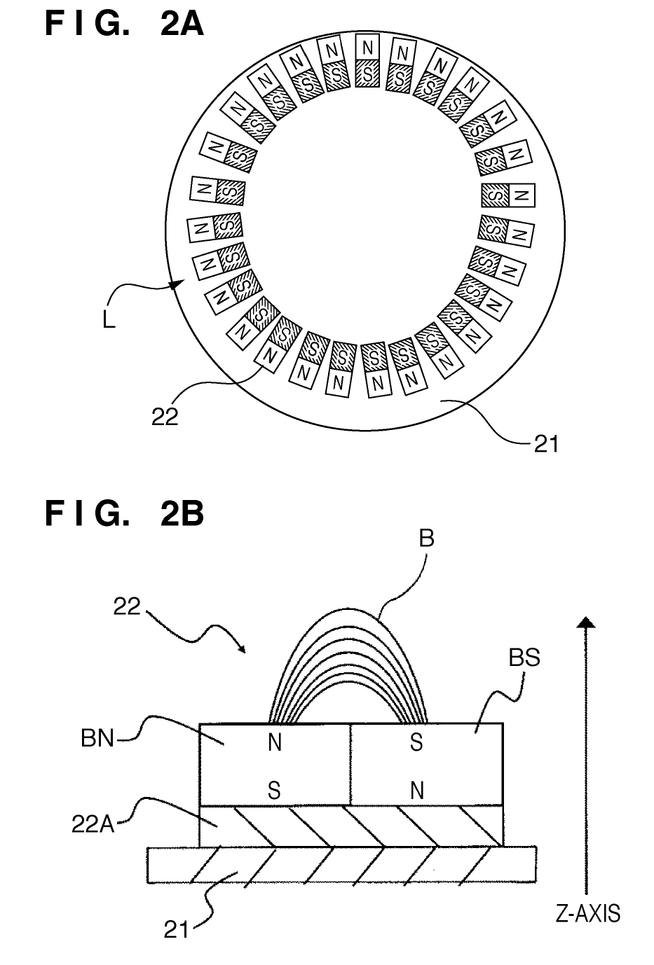

FIG. 2A is a plan view showing the magnet unit 2, and FIG. 2B is a partial side view showing the magnet unit 2.

As described above, the magnet unit 2 includes the plate 21 made of a material such as a metal, and a plurality of magnet pieces 22 attached to the plate 21.

Each magnet piece 22 includes two magnets (first and second magnet members) BN and BS magnetized in a direction perpendicular to the plate 21 (direction perpendicular to the target 41). The two magnets BN and BS are arranged side by side while their magnetic poles facing the target 41 are opposite to each other. This arrangement forms a magnetic field B by tunnel-like magnetic lines of force which emerge from one magnet BN toward the target 41 and converge to the end of the other magnet BS. The two magnets are arranged so that heteropolar ends serving as portions having the strongest magnetic force in the magnets are adjacent to each other. This arrangement forms the magnetic field B which is strong at the vicinity and hardly diverges to a distant position. Ends of the magnets BN and BS that are opposite to the target 41 are attached to the plate 21 via an intermediate plate 22A. The intermediate plate 22A is preferably made of a high-magnetic-permeability material or soft magnetic material (for example, magnetic SUS). The intermediate plate 22A magnetically couples the ends of the magnets BN and BS, or shields the magnetic field from the outside of the magnet unit 2. The material of the magnets BN and BS is not particularly limited in the present invention, and a steel magnet, ferrite magnet, and rear earth magnet are available. An Nd—Fe magnet is preferable for high magnetic flux density. Also, the material of the plate 21 is not particularly limited and is Al or the like.

In the example of FIG. 2A, a plurality of magnet pieces 22 described above are arranged in a positional relationship in which the tunnels of magnetic lines of force are coupled endlessly. More specifically, the orientations of the magnet pieces 22 are aligned so that one magnetic pole faces inward and the other magnetic pole faces outward. The magnet pieces 22 are arranged like a ring at intervals between them in the circumferential direction. The magnet pieces 22 are preferably arranged in a ring shape (annular shape) to form a ring-like magnetic field horizontally in a radial direction along the surface of the target 41. The annular shape is not limited to a circular shape as long as it is endless. Electrons drift to revolve around the endless magnetic field, and keep rotating on the surface of the target 41, generating ions by collision with gas. Then, a high-density plasma is formed at a portion where magnetic lines of force cross an electric field formed in a direction perpendicular to the surface of the target 41, that is, a point where the magnetic flux density in a direction parallel to the surface of the target 41 (to be referred to as “horizontal magnetic flux density”) is high (planar magnetron discharge). Note that the magnetic pole direction of the magnet piece 22 is not limited to one shown in FIG. 2A, and may be reversed.

The above-described balanced magnet pieces which are devised by the present inventors and arranged so that opposite magnetic poles of the two magnets BN and BS are adjacent to each other have a structure which maximizes the attenuation factor of the magnetic flux density along the Z-axis (direction perpendicular to the surface of the target 41). This structure can form a strong horizontal magnetic field near the target 41 to increase the plasma density. In addition, this structure can suppress generation of charge-up damage because the horizontal magnetic flux density attenuates near the substrate.

The use of the balanced magnet pieces has two other advantages. First, the single magnet piece 22 can form the magnetic flux density of a horizontal component on the surface of the target 41, and the erosion track shape can be easily imaged. Second, a single magnet piece can determine the attenuation state of the magnetic flux density toward the substrate 8. Thus, an optimal erosion track shape can be examined without considering a change of the magnetic flux density at the substrate position that causes charge-up damage.

In the example of FIG. 2A, an annular magnetic field L is formed along the periphery of the plate 21 in accordance with the arrangement of the magnet pieces 22. The magnet pieces 22 are arranged so that the annular magnetic field L is decentered from the rotating shaft 3. This design can uniform a magnetic field formed on the surface of the target 41.

Note that an application of the present invention is not limited to the above embodiment. For example, the number of annular magnetic fields is not limited to one in the magnet unit 2, and a plurality of annular magnetic fields may be formed in a nested shape or separate regions. In this case, if annular magnetic fields are adjacent to each other (at an interval), it is preferable to determine the orientations of the magnet pieces 22 in the respective annular magnetic fields so that homopolar ends of the magnet pieces 22 are adjacent to each other (at an interval).

Further, the above embodiment uses identical magnet pieces 22, but magnet pieces 22 for forming a magnetic field with different strengths depending on locations may coexist to form an annular magnetic field. Even the magnets BS and BN forming the magnet piece 22 may differ in magnetic flux density, height, and shape. However, to converge magnetic lines of force to adjacent magnets, magnets are preferably almost equal in magnetic flux density, height, and shape. For example, it is preferable that the magnetic flux strength and height on the magnetic pole end face is not different by more than 1.5 times between the magnets.

[Electronic Component Manufacturing Method]

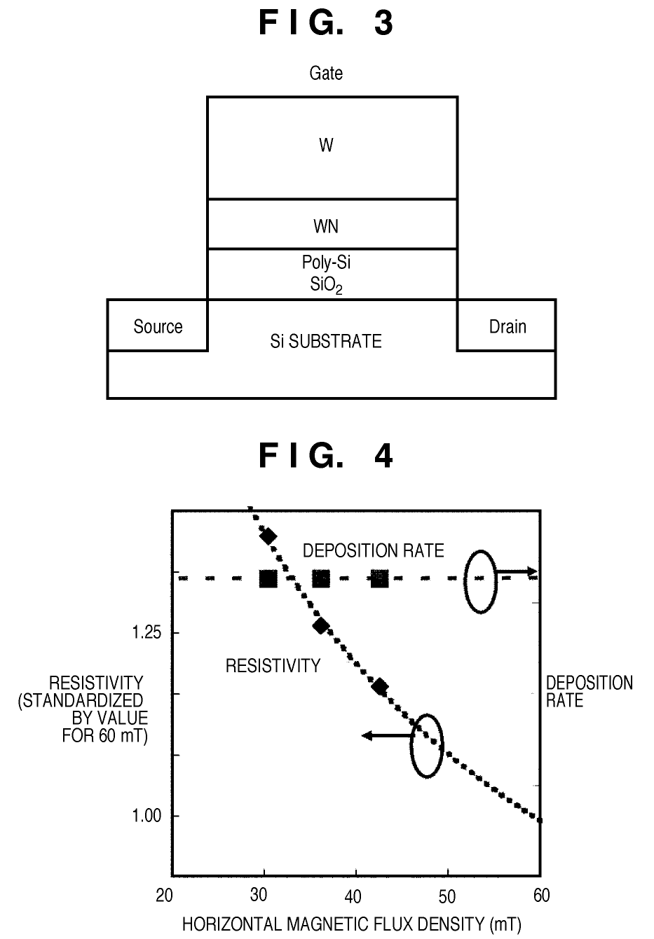

The manufacture of a DRAM (Dynamic Random Access Memory) as a typical memory among the semiconductor devices will be exemplified. FIG. 3 shows the sectional structure of a field effect transistor which forms a DRAM memory cell. In the example of FIG. 3, an SiO₂ layer serving as a gate insulating film is formed on an Si surface by heating and oxidation, and a refractory WN/W layer is formed as a gate electrode on a poly-Si film. This structure can reduce the wiring resistance while holding the function of the Si gate. The gate electrode material and gate insulating film material are not limited to them.

The embodiment uses the magnetron sputtering apparatus shown in FIG. 1 when forming the gate electrode on the gate insulating film. The magnetron sputtering apparatus can deposit a low-resistance gate electrode and prevent charge-up of the gate insulating film.

FIG. 4 shows the measurement result of the relationship between the horizontal magnetic flux density and the resistivity of the W film near the target. Referring to FIG. 4, the value of the resistivity (Ω·cm) is a relative value when a resistivity for a horizontal magnetic flux density of 60 mT is defined as 1. As shown in FIG. 4, the resistivity of the W film can be reduced by increasing the horizontal magnetic flux density while maintaining the deposition rate. It is considered that the plasma impedance decreases upon an increase in plasma density near the target and as a result, the target potential drops, suppressing the energy of ions entering the target and preventing mixture of recoil Ar or the like in the film. In other words, a high-quality film can be deposited by increasing the magnetic flux density near the target.

### Example

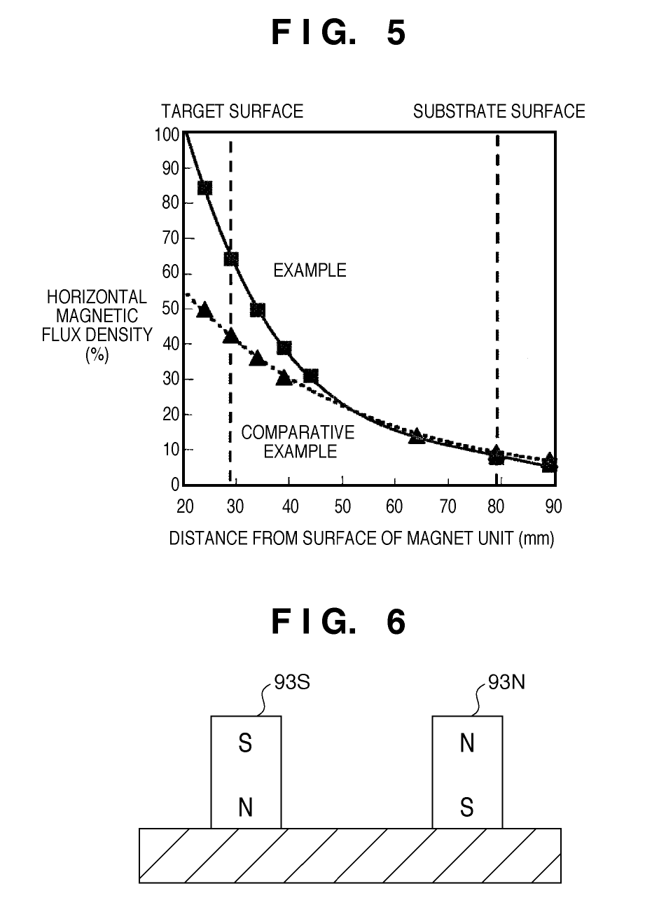

FIG. 5 is a graph showing the relationship between the distance from the target surface and the horizontal magnetic flux density for the magnet unit 2 in Example and Comparative Example. Referring to FIG. 5, the horizontal magnetic flux density is given by a relative value when the value of the horizontal magnetic flux density at a distance of 20 mm from the surface of the magnet unit is defined as 100(%) in the use of the magnet unit in Example. The magnet unit 2 in Example forms an annular magnetic field by arranging the magnet pieces 22 shown in FIG. 2B. To the contrary, a magnet unit in Comparative Example forms an annular magnetic field by arraying a plurality of rod-like magnets 93S and 93N magnetized in a direction perpendicular to the target surface as shown in FIG. 6 to be spaced apart from each other so that the horizontal magnetic flux density on the substrate surface becomes equal to that in Example. In the graph of FIG. 5, the ordinate indicates the average value of the horizontal magnetic flux density. This average value was obtained by extracting only points where the horizontal component of a magnetic flux density at a predetermined distance from the magnet unit became five times or more of the vertical component, and averaging magnetic flux densities at these points. Note that measurement of the magnetic field B used a 3D magnetic field measuring device for measuring a magnetic flux density on the surface of a magnetized magnet by a probe. The gaussmeter and Hall probe of the magnetic field measuring device cope with triaxial measurement and can detect magnetic flux densities in the X, Y, and Z directions.

As a result, the horizontal magnetic flux density on the target surface was 64.2% for the magnet unit in Example, which was about 1.5 times higher than 42.6% for the magnet unit in Comparative Example. However, it was confirmed that the magnetic flux density near the substrate was almost equal between the two magnets (8% in Comparative Example and about 6% in Example). It is preferable to use the magnet unit 2 which implements a horizontal magnetic flux density attenuation factor of ⅙ or less from the target surface to the wafer surface.

Further in the magnet unit of Example, the attenuation factor (horizontal magnetic flux density obtained at a position corresponding to each magnet piece 22) is fixed for each magnet piece 22. It suffices to consider only the in-plane distribution, and a magnet array for obtaining a target horizontal magnetic flux density could be easily determined. However, in the magnet unit of Comparative Example, densities obtained on the target surface and near the substrate changed depending on the distance between the heteropolar magnets 93S and 93N and that between the homopolar magnets 93S or 93N. It was cumbersome to determine a magnet array.

The present invention is not limited to the above-described embodiment, and various changes and modifications can be made within the spirit and scope of the present invention. Therefore, to apprise the public of the scope of the present invention, the following claims are made.

1. A magnetron sputtering apparatus comprising:
a cathode electrode having a first surface capable of attaching a target and a second surface opposite to the first surface; and
a magnet unit which is adjacent to the second surface of said cathode electrode and forms a magnetic field on a surface of the target,
said magnet unit including a plurality of magnet pieces each having a first magnet member which is magnetized in a direction perpendicular to the surface of the target and is arranged with a magnetic pole end face oriented toward the target, and a second magnet member which is magnetized opposite to the first magnet member in the direction perpendicular to the target and is arranged in contact with the first magnet member with a magnetic pole end face being oriented toward the target,
wherein the plurality of magnet pieces are arranged like a ring spaced each other in a circumferential direction to form a ring-like magnetic field for magnetron sputtering on the surface of the target,
wherein said magnet unit is adapted to be rotatable around an rotating shaft perpendicular to the surface of the target and to form a magnetic field in a direction rotating along the surface of the target, and
wherein the plurality of magnet pieces are arranged so that the center of the ring-like magnetic field is decentered from the rotating shaft.

2. The magnetron sputtering apparatus according to claim 1, wherein
said magnet unit includes a support member to which the plurality of magnet pieces are attached, and
the magnet pieces include a coupling member which connects magnetic pole end faces of the first magnet members and the second magnet members on a side of the support member, and attaches the first magnet members and the second magnet members to the support member.

3. The magnetron sputtering apparatus according to claim 2, wherein one of the first magnet member and the second magnet member forming each of the plurality of magnet pieces is arranged at a periphery of the support member, and the other magnet member is arranged inside with respect to said one magnet member.

4. The magnetron sputtering apparatus according to claim 2, wherein the coupling member is formed from a material higher in magnetic permeability than the support member.

5. An electronic component manufacturing method comprising a deposition step of depositing a film on a substrate by magnetron sputtering using a magnetron sputtering apparatus defined in claim 1.

6. A method of manufacturing an electronic component including:
a substrate, at least part of a surface of which is formed from a semiconductor layer,
a gate electrode formed on the substrate, and
a gate insulating film between the substrate and the gate electrode,
wherein the method comprises a forming step of forming the gate insulating film using a magnetron sputtering apparatus defined in claim 1.

7. The magnetron sputtering apparatus according to claim 1, wherein one or more magnet pieces which form different magnetic field intensities are mixed in the plurality of magnet pieces.
